(19) United States
(12) Patent Application Publication
(10) Pub. No.: US 2008/0296690 A1
(43) Pub. Date: Dec. 4, 2008

(54) Metal interconnect System and Method for Direct Die Attachment

(75) Inventors: Samuel S. Anderson, Tempe, AZ (US); Zheng Shen, Ovieda, FL (US); David N. Okada, Chandler, AZ (US)

Correspondence Address: GOODWIN PROCTER LLP;PATENT ADMINISTRATOR, 53 STATE STREET, EXCHANGE PLACE, BOSTON, MA, 02109-2881, US

(73) Assignee: Great Wall Semiconductor Corporation, Tempe, AZ (US)

(21) Appl. No.: 10/581,950

(22) PCT Filed: Dec. 11, 2004
(86) PCT No.: PCT/US2004/044097

§ 371 Date: Aug. 18, 2008

Related U.S. Application Data
(60) Provisional application No. 60/529,166, filed on Dec. 12, 2003.
(60) Provisional application No. 60/544,702, filed on Feb. 12, 2004.

(51) Int. Cl. H01L 23/488; H01L 21/60; H01L 27/088

(52) U.S. Cl. 257/368; 438/612; 257/762; 257/E21.513; 257/E23.023; 257/E27.06

(57) ABSTRACT

Provided herein is an exemplary embodiment of a semiconductor chip for directly connecting to a carrier. The chip includes a metal layer applied to a top surface of the chip; a passivation layer applied over the metal layer such that portions of the passivation layer is selectively removed to create one or more openings (“bond pads”) exposing portions of the metal layer and one or more solderable metal contact regions formed on each of the one or more openings. The solderable metal contact regions electrically connect to the carrier when the chip is positioned face down on the carrier, supplied with a thin layer of solder and heated.

### CROSS-REFERENCE TO RELATED APPLICATIONS

This application claims the benefit of priority to U.S. Application Nos. 60/529,166 and 60/544,702, filed Dec. 12, 2003 and Feb. 12, 2004, respectively, the entire disclosures of which are hereby incorporated by reference as if set forth at length herein.

### STATEMENT REGARDING FEDERALLY SPONSORED RESEARCH OR DEVELOPMENT

Not applicable

### REFERENCE OF A “MICROFICHE APPENDIX”

Not applicable

### BACKGROUND OF THE INVENTION

1. Field of Invention

The present invention relates generally to semiconductor technology and more particularly, to a system and method for directly mounting semiconductor chips to a substrate such as a printed circuit board.

2. Brief Description of the Prior Art

A typical surface mountable semiconductor component consists of a semiconductor chip attached to a lead frame, wire bonded, and encapsulated into a plastic package with exposed leads. Soldering the leads to e.g., a printed circuit board provides mechanical, thermal, and electrical connections to the semiconductor chip.

FIG. 1—Prior Art

FIG. 1 shows an exemplary embodiment of a typical prior art wire bond chip or chip having a lead frame. Wire bonds add parasitic inductance and series resistance to electronic devices. The added inductance and resistance is undesirable for many devices, including high frequency devices, high speed devices, and low on-resistance power semiconductor devices. The lead frame provides the primary thermal conduction path for the chip. However, the thermal performance of the wire bond chip is limited by the length of the thermal path to the substrate, circuit board or carriers and the lead frame design and composition.

FIG. 2—Prior Art

Flip chip bump processing was developed to address the above shortcomings of wire bond chips. Flip chip bump assembly also called Direct Chip Attach assembly, is the process of directly attaching the chip face-down to a substrate, board or carrier, by means of conductive bumps on the chip.

Several varieties of flip chip processing exist today, including solder bump, copper pillar bump, plated bump, gold stud bump and adhesive bump.

FIG. 2A illustrates a prior art chip 210 having a solder ball bump 220 formed on the chip's under bump metallization (“UBM”) layer 260 using conventional techniques. The solder ball bump 220 electrically contacts to the silicon chip 210 enabling the chip to be directly attached face-down to the printed circuit board. A disadvantage of the solder ball approach is the limited contact area of the ball to the chip surface and to the substrate. This reduces the thermal and electrical conduction areas thereby increasing the thermal and electrical resistance. The thermal and electrical paths are long, approximately the diameter of the solder ball. The limited contact area of the ball also results in limited mechanical strength of the bond between the chip and the circuit substrate.

As shown in FIG. 2B, instead of a solder ball bump, the chip 210 may include a raised conductive region of a metallic material such as copper, nickel or other metal or alloy, with a top coating of solder. FIG. 2B illustrates the chip 210 having a copper pillar bump 230 formed on the chip's UBM layer 260 using conventional techniques. As shown, the copper pillar bump also includes a top coating of solder 240. Because copper is significantly more thermally and electrically conductive than solder the copper pillar bump 230 offers some improvement over the solder ball 220. However, the standard height of the pillar bump 230 (approx. 100 μm) adds to both the thermal and electrical resistance.

A further disadvantage is that the above flip chip processes involve multiple steps and require specialized equipment which increases the costs of the product.

### SUMMARY OF THE INVENTION

The present invention addresses the aforementioned limitations of the prior art by providing, in accordance with one aspect of the present invention, a semiconductor chip for directly connecting to a carrier, having a metal layer applied to a top surface of the chip; a passivation layer applied over the metal layer such that portions of the passivation layer is selectively removed to create one or more openings (“bond pads”) exposing portions of the metal layer and one or more solderable metal contact regions formed on each of the one or more openings. The solderable metal contact regions electrically connect to the carrier when the chip is positioned face down on the carrier, supplied with a thin layer of solder and heated.

In accordance with additional aspects of the present invention the solderable metal contact regions are approximately 1 μm thick and comprise either TiCu, TiNiAg or AlNiVCu metal layer combinations.

These and other aspects, features and advantages of the present invention will become better understood with regard to the following description, appended claims, and accompanying drawings.

### BRIEF DESCRIPTION OF THE DRAWINGS

Exemplary embodiments of the present invention are now briefly described with reference to the following drawings:

FIG. 1 depicts aspects of the prior art in accordance with the teachings presented herein.

FIG. 2 depicts additional aspects of the prior art in accordance with the teachings presented herein.

FIG. 3 depicts a third aspect of the present invention in accordance with the teachings presented herein.

FIG. 4 depicts a fourth aspect of the present invention in accordance with the teachings presented herein.

FIG. 5 depicts a fifth aspect of the present invention in accordance with the teachings presented herein.

FIG. 6 depicts a sixth aspect of the present invention in accordance with the teachings presented herein.

FIG. 7 depicts a seventh aspect of the present invention in accordance with the teachings presented herein.

FIG. 8 depicts an eight aspect of the present invention in accordance with the teachings presented herein.

### DESCRIPTION OF THE INVENTION

The aspects, features and advantages of the present invention will become better understood with regard to the following description with reference to the accompanying drawings. What follows are preferred embodiments of the present invention. It should be apparent to those skilled in the art that the foregoing is illustrative only and not limiting, having been presented by way of example only. All the features disclosed in this description may be replaced by alternative features serving the same purpose, and equivalents or similar purpose, unless expressly stated otherwise. Therefore, numerous other embodiments of the modifications thereof are contemplated as falling within the scope of the present invention as defined herein and equivalents thereto.

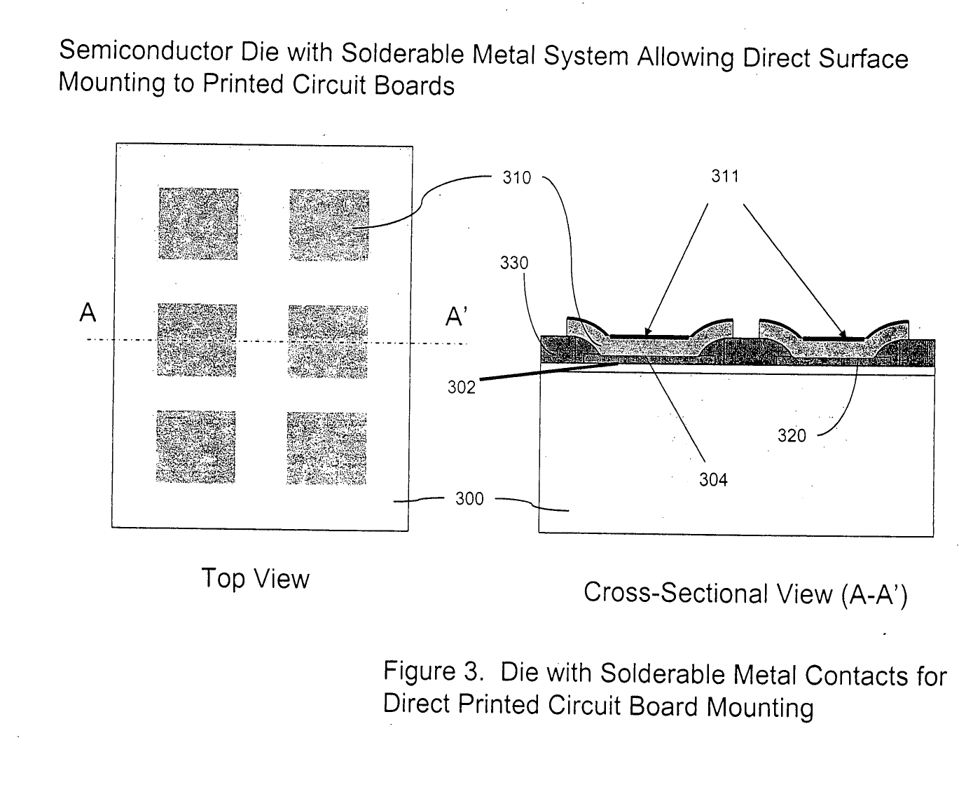

FIG. 3

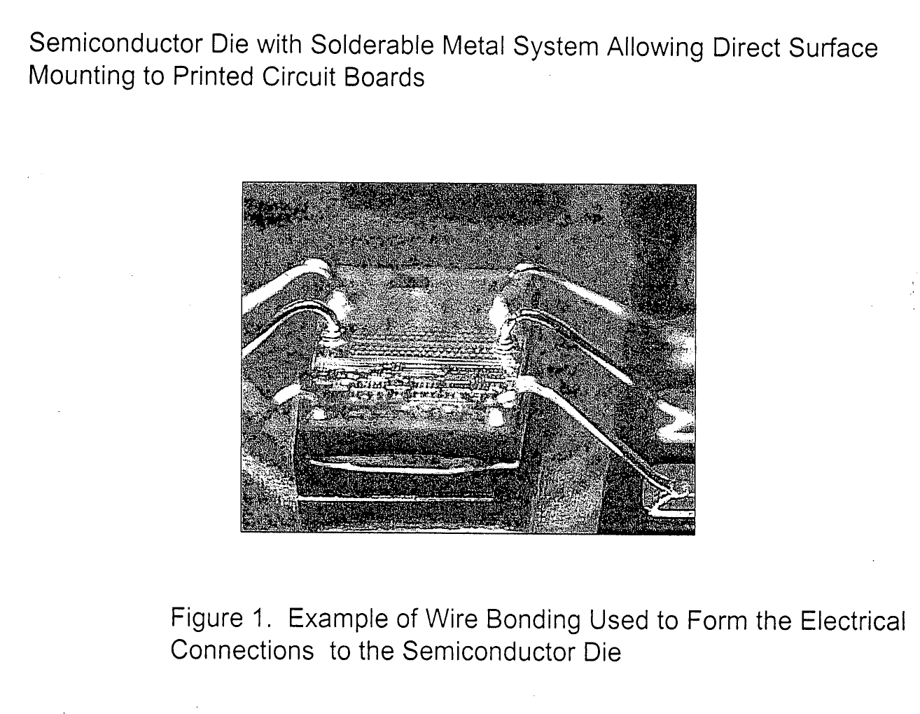

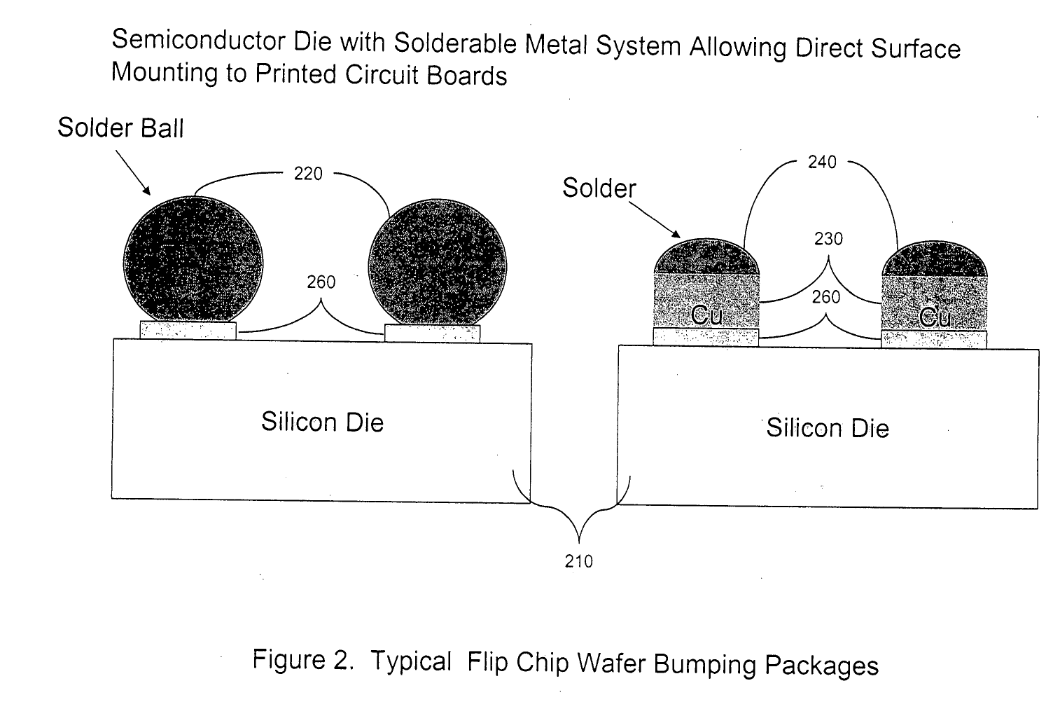

FIG. 3 depicts an exemplary embodiment of a semiconductor chip 300 constructed in accordance with the present invention. As shown, the semiconductor chip 300 includes an aluminum metal layer 302, a passivation layer 330, a plurality of “bond pads” or openings 304 in the passivation layer 330 to expose portions of the underlying metal layer 302 and a plurality of solderable electrical metal contact regions 310. The solderable electrical metal contact regions 310 are formed on the bond pads 304 and are made of materials similar to those of the UBM layer 260 in FIGS. 1 & 2. The solderable metal contact regions 310 allow the chip 300 to be directly soldered to a substrate such as a printed circuit board. Preferably, the solderable metal contact regions 310 are approximately 1 μm thick and are made of two or three layers of conductive metals, such as TiCu, TiNiAg or AlNiVCu metal layer combinations. Optionally, the solderable metal contact regions 310 may include an additional film layer of solder 311 to prevent oxidation of exposed metal and to facilitate the chip's attachment to the substrate.

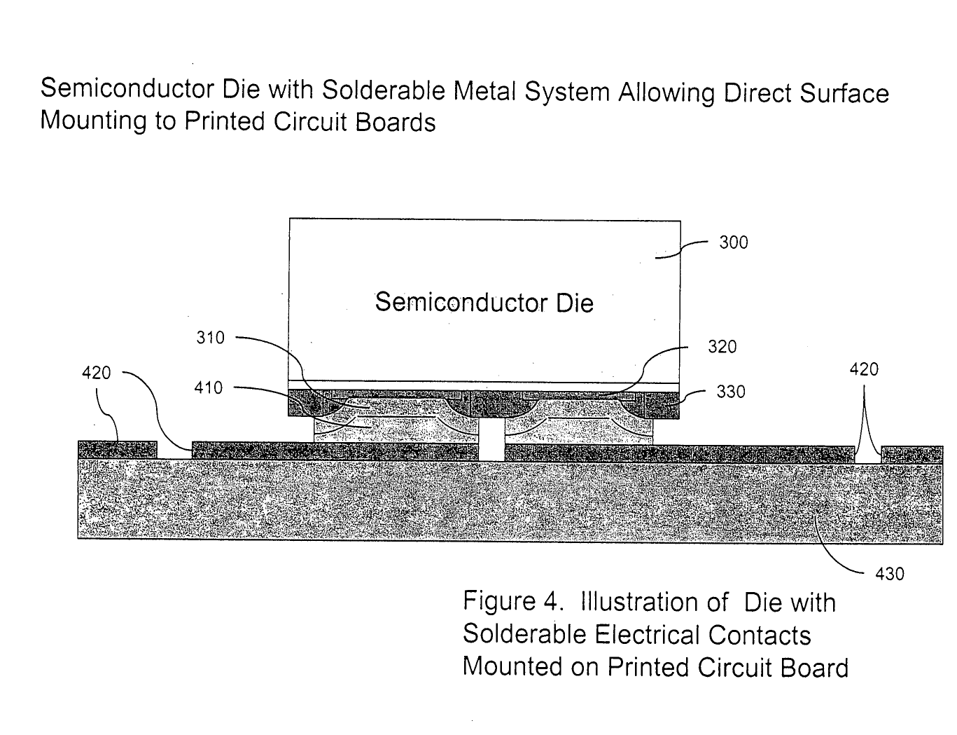

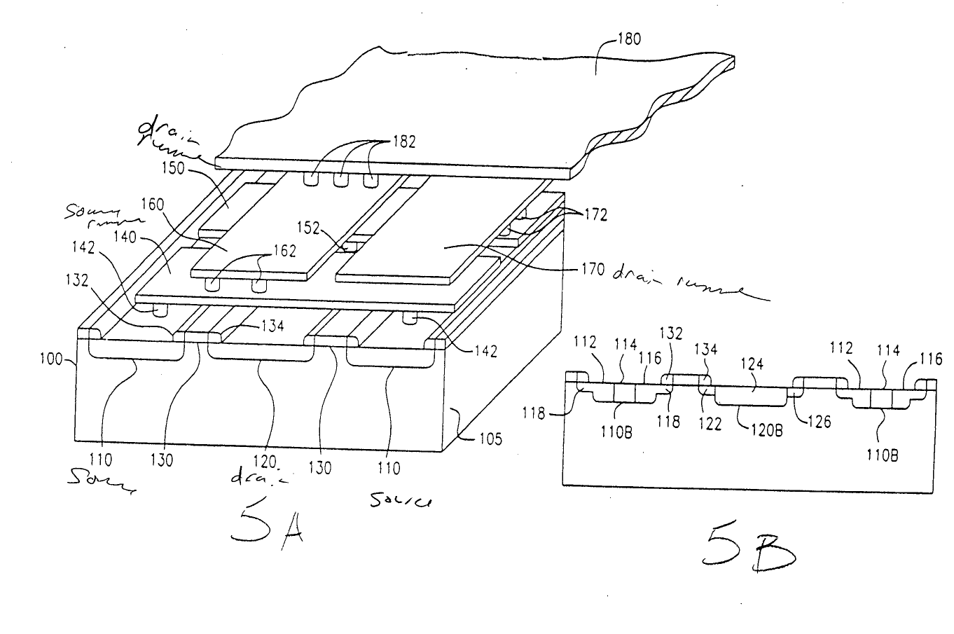

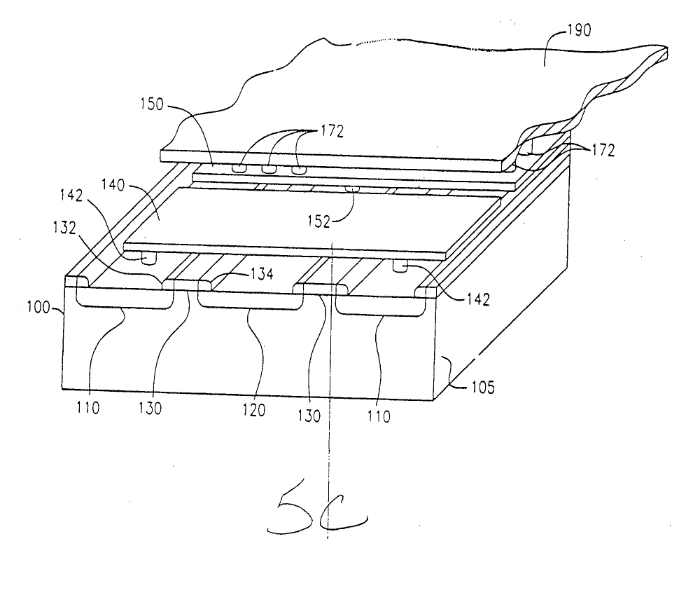

FIG. 4

FIG. 4 depicts an exemplary embodiment of a chip 300 mounted onto a printed circuit board in accordance with the present invention's teachings herein. As shown, the chip 300 is flipped and mounted to a circuit board 430 using conventional surface mount techniques. A thin layer of solder paste 410 can be deposited with a stencil onto the printed circuit board 430. The chip 300 is then placed into the proper location and lowered until it is in contact with paste 410. The printed circuit board 430 assembly is then heated to approximately 200° C. until the solder reflows. The solderable metal contact regions 310 on the chip are then directly soldered to the copper printed circuit board traces 420 thereby forming a mechanical, electrical, and thermal connection.

If the solderable metal contact regions 310 include the optional solder layer, it is not necessary to apply the solder paste 410. The solder layer, once reflowed, will be sufficient to attach the chip to the printed circuit board, further simplifying the assembly process.

A semiconductor chip 300 of the present invention may be fabricated as follows: using conventional techniques, first, a semiconductor chip is prepared having at least one aluminum layer on the surface of the chip. Next, a passivation layer is applied over the surface of the chip, portions of which is selectively removed to create one or more openings or bond pads to expose a top aluminum layer. Next, solderable metal contact regions 310 are formed on each of the bond pads using conventional sputtering, plating, and patterning processes. Optionally, a thin film of solder may be applied over the solderable metal contact regions to facilitate direct chip attachment to a substrate.

The present invention is applicable to all types of semiconductor chips, including integrated circuits, discrete semiconductor devices, sensors, micro-machined structures, etc. The present invention has several advantages over existing techniques including the following: 1) simplicity of semiconductor packaging; 2) ease of manufacturing; 3) simplicity of mounting device to the printed circuit board; 4) enhanced thermal performance of the package; 5) very short thermal path from the semiconductor chip to the printed circuit board; 6) contact areas can be maximized to increase area of thermal path; thereby reducing the thermal resistance; 7) very low electrical resistance from chip surface to the printed circuit board; 8) short current path from chip to printed circuit board; 9) contact areas can be increase to further minimize the series resistance; and 10) no wire bond or lead frame inductance and resistance.

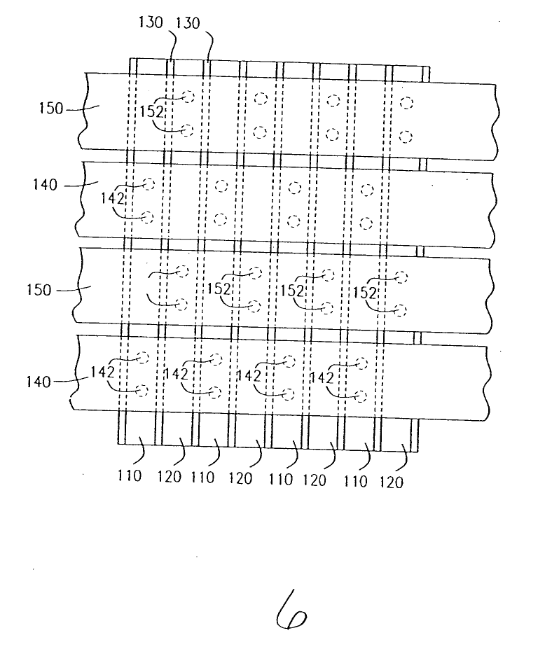

FIG. 5

FIGS. 5A-C depict exemplary alternative embodiments of a chip 100 in accordance with the present invention's teachings herein. Specifically, FIG. 5A illustrates a portion of the device having a substrate 105, two sources 110 and a drain 120. In addition, device 100 is shown as a P substrate 105. In another embodiment, the P substrate is deposited on top of a P− substrate.

Sources 110 and drain 120 are preferably n-type dopants implants into P substrate 105. It will be appreciated that the variations of the design of the sources and drains are known to one skilled in the art and within the scope of the present invention. For example, sources 110 and drain 120 could be p-type dopant implants into an N substrate 105

As another example FIG. 5B shows a preferred embodiment where sources 110B is comprised of a region 112 which is doped as N+ region 114, which is doped as P+ and the region 116 is doped N. In an alternate embodiment, source 110B is comprised of region 114 doped P+, and regions 112 and 116 are N+ implants adjacent to either side of the P+ region 114. In yet another embodiment, regions, 112 and 114 also have a region 118. Region 118 may be a lightly doped N− Implant while the rest of region 112 and 114 are N+. Region 118's lightly doped N−Implant functions as a lightly doped drain.

Drain 120B, in this example, is comprised of region 124 doped as N+ and regions 124 and 126 doped as N. As with source 110B, it is within the scope of this invention and the skill of one skilled in the art to vary the doping.

Referring back to FIG. 5A gate 130 is comprised of a polysilicon gate over a SiO2 or Si3N4 insulating layer and is placed between source 110 and drain 120. Adjacent are spacers 132 and 134 preferably comprised SiO2 or Si3N4, and partially extending over source 110 and drain 120 respectively. (FIG. 1B also shows spacers 132 and 134 extending over regions 118 and 122. Spacers also extend over regions 126.)

Source runners 140 and drain ruiners 170 formed on second interconnect layer and is preferably comprised of metal, although other conductive materials may be used. Source runner 160 interconnects source runners 140 using Vias 162. Preferably, source runners 160 are in substantially parallel orientation with respect to source 110, although other orientations that are not parallel may be used.

Drain runners 150 are interconnected by drain runners 170 using vias 172. Preferably, drain runner 170 is substantially parallel orientation with respect to drain 120, although other orientations that are not parallel may be used.

Like the first interconnect layer, only one source and drain runners 160 and 170, respectively are shown, but in the preferred embodiment multiple sources and drain runners 160 and 170 would be used and are, preferably, interleaved with each other.

Although the runners shown in FIG. 5A are substantially of equal widths and rectangular, runners can be of any shape. For instance, runners may be of unequal widths and runners may have varying narrow and wider portions or rounded corners.

FIG. 5A shows source pad-solderable metal contact region 180 formed on a third interconnect layer, which is preferably comprised of metal, although other conductive materials may be used. Source pad 180 is connected to source runners 160 using vias 182. Although not shown in FIG. 5a for the sake of clarity, similar drain pads-solderable metal contact regions connect drain runners 170 and like wise for gate pads-solderable metal contact regions.

In the preferred embodiment the vias from conductive interconnects and are comprised preferably out of tungsten, although other conductive material may be used. These are formed in a manner that are well-known to those skilled in the art.

In another embodiment, no second interconnect layer is used for runners. As an example, FIG. 5c shows an embodiment similar to FIG. 5a except there is no second interconnect layer forming source 160 and drains 170. Instead, drain pad-solderable metal contact regions 190 is formed on the second interconnect layer and is connected to drain runners 150 by vias 172. Although not shown in FIG. 5c for the sake of clarity, similar source pads-solderable metal contact regions connect source runners 140.

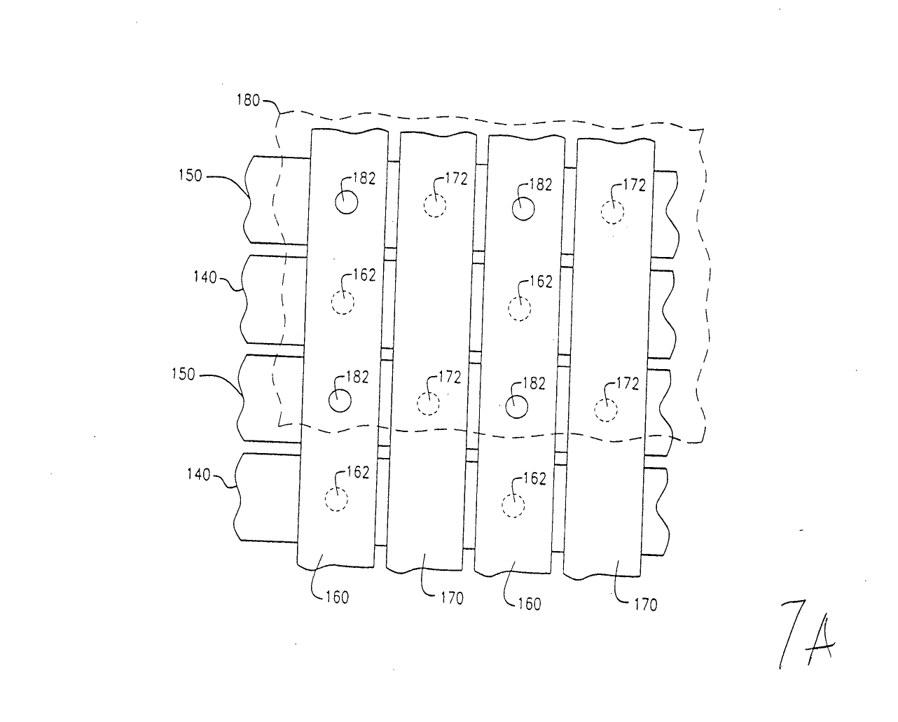

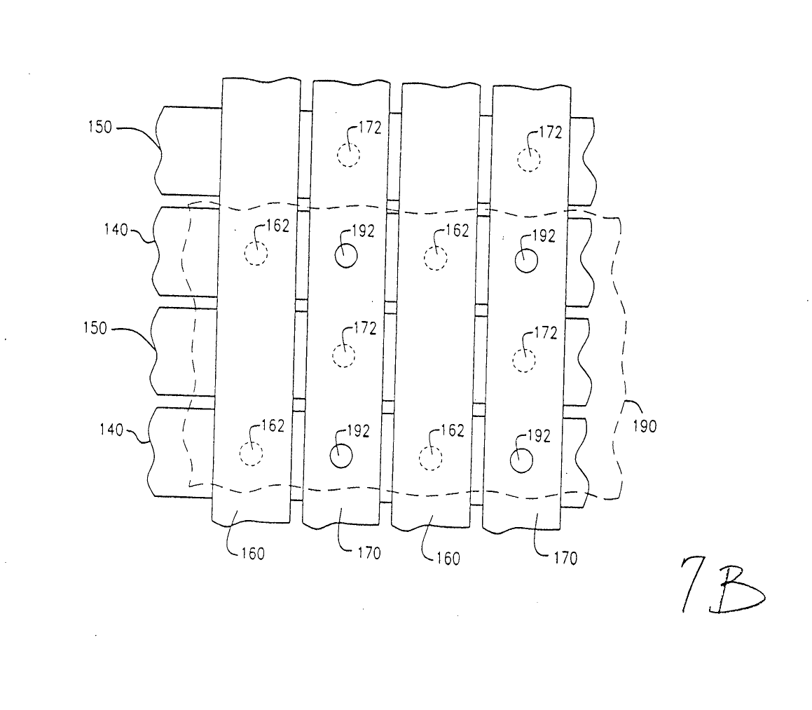

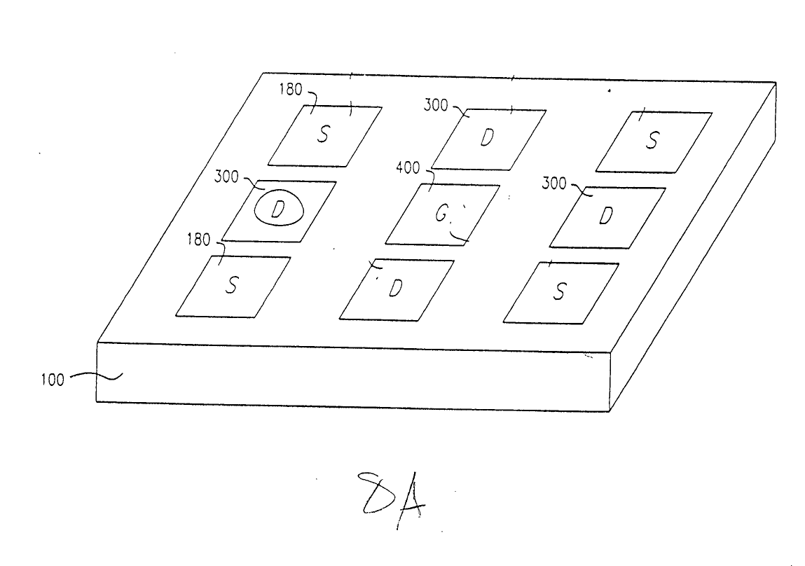

Referring now to FIG. 6 there is no top plan view of the embodiment shown in FIG. 1a and showing additional sources 110, drains 120 and first layer interconnect source runners 140 and drains runners 150. Sources 110 and drains 120 are shown having substantially vertical orientation while source runners 140 and drain ruiners 150 are shown in substantially horizontal orientation. Also, shown are vias 142 and 152 interconnecting the source runners 140 and drain runners 150 to sources 110 and drains 120, respectively. It should be noted that although FIG. 6, for instance, shows at a point of connection the use of two vias, one via could be used as shown in FIG. 7a, or more than two, as shown in FIG. 5a for vias 182.

Referring to FIG. 7a there is a top plan view showing the first interconnect layer (forming source runner 140 and drain runners 150), second interconnect layer (forming source runner 160 and drain runners 170) and third interconnect layer forming source pad-solderable metal contact regions 180.

Source runners 140 and drain runners 150 are laid out in substantially horizontal orientation. Source runners 160 overlay source runners 140 and are interconnected using vias 172. Source pad-solderable metal contact regions 180 is shown in FIG. 7a overlaying source runners 160 and drain runners 170, but is only connected to source runners l60 by vias

FIG. 7b shows the top plan view of the embodiment of FIG. 5a showing the first interconnect (forming source runners 140 and drain runners 150), second interconnect layer (forming source runners 160 and drain runners 170) and a third interconnect layer forming a drain pad-solderable metal contact regions 190 (in outline form)

Source runners 140 and drain runners 150 are laid out substantially horizontal orientation. Source runners 160 overlay source runners 140 and interconnect source runners 140 using vias 162. Drain runners 170 overlay drain runners 150 and interconnect drain runners 170 using vias 172. Drain pad-solderable metal contact regions 190 is shown overlaying source runners 160 and drain runners 170, but is only connected to drain runners 170 by vias 192.

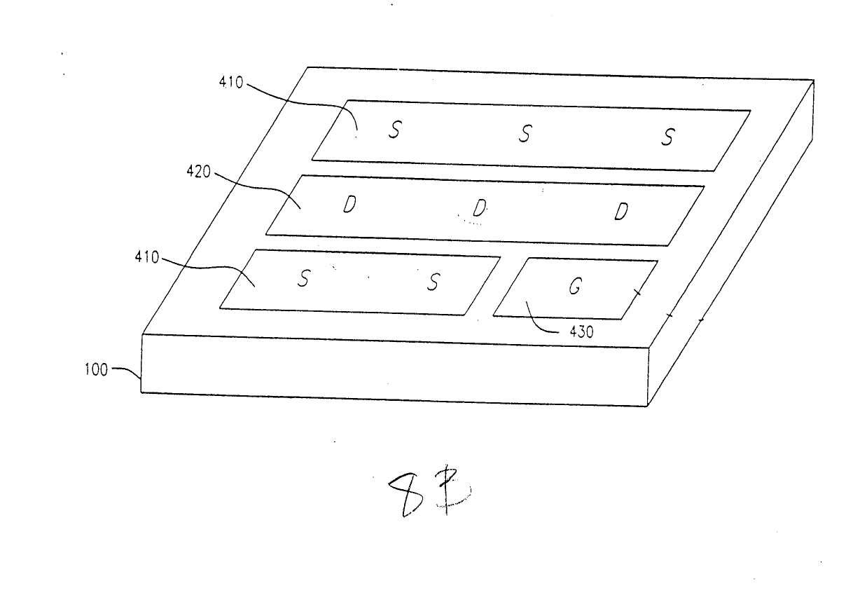

FIG. 8 shows the top of the device 100 with source pads-solderable metal contact region 180, analogous drain pad-solderable metal contact region 300 and gate pad-solderable metal contact regions 400. In the embodiment shown in FIG. 8, the source and drain pads-solderable metal contact regions are arranged in a checker board layout.

FIG. 8 b shows an alternative layout where each source pad-solderable metal contact regions 410 and drain pad-solderable metal contact regions 420 are shaped stripes and are interleaved with each other. In the preferred embodiment gate pad-solderable metal contact regions 430 would be placed with a shortened source pad 410 or shortened drain pad-solderable metal contact regions 420 as needed.

### CONCLUSION

Having now described preferred embodiments of the invention, it should be apparent to those skilled in the art that the foregoing is illustrative only and not limiting, having been presented by way of example only. All the features disclosed in this specification (including any accompanying claims, abstract, and drawings) may be replaced by alternative features serving the same purpose, and equivalents or similar purpose, unless expressly stated otherwise. Therefore, numerous other embodiments of the modifications thereof are contemplated as falling within the scope of the present invention as defined by the appended claims and equivalents thereto.

1. A method of fabricating a semiconductor chip for direct attachment to a carrier, said method comprising the steps of:
providing a partially manufactured chip having a top surface;
applying a metal layer over said top surface of said chip;
applying a passivation layer over said metal layer;
selectively removing a portion of said passivation layer to define an opening exposing a portion of said metal layer; and
forming a solderable metal contact region on said opening,
wherein said solderable metal contact region is suitable for electrically connecting to said carrier upon positioning said chip face down on said carrier, supplying a thin layer of solder to said solderable metal contact region, and applying heat to the thin layer of solder.

2. The method as in claim 1 wherein said solderable metal contact region comprises a material selected from the group consisting of a TiCu metal layer combination, a TiNiAg metal layer combination and an AlNiVCu metal layer combination.

3. The method as in claim 1 wherein said metal layer comprises aluminum.

4. The method as in claim 1 wherein said solderable metal contact region has a thickness of approximately 1 μm.

5. A semiconductor chip suitable for being directly connected to a carrier, said semiconductor chip comprising:
a metal layer applied to a top surface of said chip;
a passivation layer applied over said metal layer defining an opening, said opening exposing a portion of said metal layer; and
a solderable metal contact region disposed on said opening,
wherein said solderable metal contact region is suitable for electrically connecting to said carrier when said chip is positioned face down on said carrier, supplied with a thin layer of solder, and heated.

6. The semiconductor chip as in claim 5 wherein said metal contact region comprises a material selected from the group consisting of a TiCu metal layer combination, a TiNiAg metal layer combination, and an AlNiVCu metal layer combination.

7. The semiconductor chip as in claim 5 wherein said metal layer comprises aluminum.

8. The semiconductor chip as in claim 5 wherein said solderable metal contact region has a thickness of approximately 1 μm.

9. A semiconductor device comprising:
(a) a first doped region defined in a semiconductor substrate, said first doped region comprising a source;
(b) a second doped region defined in said semiconductor substrate, said second doped region comprising a drain;
(c) a first connectivity layer comprising a first runner and a second runner, said first runner being operatively connected to said first doped region and said second runner being operatively connected to said second doped region;
(d) a second connectivity layer operatively connected to said first connectivity layer and comprising a third runner and a fourth runner, said third runner being operatively connected to said first runner and said fourth runner being operatively connected to said second runner.
(e) a third connectivity layer comprising a first pad operatively connected to said third runner and a second pad operatively connected to said fourth runner.

10. The semiconductor device as in claim 9 wherein each of said first and second pads has at least one of a first copper pillar and a metal layer disposed thereon.

11. The semiconductor device as in claim 10 wherein said first pad is interleaved with said second pad.

12. The semiconductor device as in claim 9 wherein said source is a source for a transistor and said drain is a drain for a transistor.

13. The semiconductor device as in claim 12 wherein said source and said drain are laid out in a substantially elongated shape, and said source is interleaved with said drain.

14. The semiconductor device as in claim 12 further comprising a plurality of the sources and drains.

15. A lateral discrete power MOSFET device comprising:
(a) a first doped region defined in a semiconductor substrate forming a source;
(b) a second doped region in said semiconductor substrate forming a drain; and
(c) a first connectivity layer,
wherein a first portion of the first connectivity layer is operatively connected to said first doped region and a second portion of the first connectivity layer is operatively connected to said second doped region.

16. The lateral discrete power MOSFET device as in claim 15 further comprising a second connectivity layer operatively connected to said first doped region through said first connectivity layer.

17. The lateral discrete power MOSFET device as in claim 16 wherein said second connectivity layer is operatively connected to said second doped region through said first connectivity layer.

18. The lateral discrete power MOSFET device as in claim 15, further comprising a third connectivity layer comprising a first pad and a second pad, wherein said first pad is operatively connected to the first portion of said first connectivity layer and said second pad is operatively connected to the second portion of said first connectivity layer.

19. The lateral discrete power MOSFET device as in claim 18 wherein said first pad comprises at least one of a first copper pillar bump, a copper direct attach, and a solder bump and said second pad comprises at least one of a second copper pillar bump, a copper direct attach, and a solder bump.

20. The lateral discrete power MOSFET device as in claim 19, further comprising a plurality of said first pads and a plurality of said second pads, wherein said first pads and said second pads are arranged in a substantially checkerboard pattern.

21. The lateral discrete power MOSFET device as in claim 19 wherein said first pad is interleaved with said second pad.

22. The lateral discrete power MOSFET device as in claim 15 wherein said source and said drain are laid out in a substantially elongated shape and wherein said source is interleaved with said drain.

23. The lateral discrete power MOSFET device as in claim 15 wherein said source and said drain are laid out in substantially checkerboard pattern.

24. A lateral discrete power MOSFET comprising:
(a) a first doped region formed in a semiconductor substrate, said first doped region defining a source;
(b) a second doped region formed in said semiconductor substrate, said second doped region defining a drain;
(c) a first connectivity layer comprising a first runner operatively connected to said first doped region and a second runner operatively connected to said second doped region; and
(d) a second connectivity layer comprising a first pad operatively connected to said first runner and a second pad operatively connected to said second runner.

25. The lateral discrete power MOSFET as in claim 24 wherein said first pad has at least one of a copper pillar bump, a copper direct die attach, and a solder bump disposed thereon, and said second pad has at least one of a second copper pillar bump, a copper direct die attach, and a solder bump disposed thereon.

26. The lateral discrete power MOSFET as in claim 25, further comprising a plurality of the first pads and a plurality of the second pads.

27. The lateral discrete power MOSFET as in claim 25 wherein said first pad is interleaved with said second pad.

28. The lateral discrete power MOSFET as in claim 24 wherein said source and said drain are laid out in a substantially elongated shape and wherein said source is interleaved with said drain.

29. The lateral discrete power MOSFET as in claim 24, further comprising a plurality of the sources and a plurality of the drains.

30. (canceled)

31. The semiconductor device as in claim 9, further comprising a plurality of the first pads and a plurality of the second pads.

32. The semiconductor device as in claim 31, wherein said first pads and said second pads are arranged in a substantially checkerboard pattern.

33. The semiconductor device as in claim 14, wherein said sources and said drains are laid out in a substantially checkerboard pattern.

34. The lateral discrete power semiconductor MOSFET as in claim 26, wherein said first pads and said second pads are arranged in a substantially checkerboard pattern.

35. The lateral discrete power semiconductor MOSFET as in claim 29, wherein said first pads and said second pads are arranged in a substantially checkerboard pattern.
